(19) United States
(12) Patent Application Publication
(10) Pub. No.: US 2022/0206746 A1
(43) Pub. Date: Jun. 30, 2022

(54) SORTING DEVICE, SELECTING SYSTEM, SORTING METHOD, AND NONTRANSITORY COMPUTER READABLE MEDIUM

(71) Applicant: NEC Corporation, Minato-ku, Tokyo (JP)

(72) Inventor: Norifumi KAMIYA, Tokyo (JP)

(73) Assignee: NEC Corporation, Minato-ku, Tokyo (JP)

(21) Appl. No.: 17/604,075

(22) PCT Filed: Apr. 19, 2019
(86) PCT No.: PCT/JP2019/016773

§ 371 Date: Oct. 15, 2021

(51) Int. Cl. G06F 7/24; G06F 7/02; G06F 7/76

(52) U.S. Cl. CPC G06F 7/24; G06F 7/76; G06F 7/02

(57) ABSTRACT

An object is to provide a sorting device, a selecting system, a sorting method, and a program capable of preventing a decrease in processing speed and an increase in the number of processing steps. The sorting device includes a rank computation device (101) that performs, in parallel, comparisons of numerical data Dₖ (k is an integer from 0 to n−1) included in numerical data D₀ to Dₙ₋₁ (n is an integer of 1 or more) with each of the numerical data D₀ to Dₙ₋₁ excluding the numerical data Dₖ, and computes a rank indicating a value level of the numerical data Dₖ in the numerical data D₀ to Dₙ₋₁ by using each comparison result, and a selection device (102) that rearranges the numerical data D₀ to Dₙ₋₁ in order on the basis of ranks of the numerical data D₀ to Dₙ₋₁.

### TECHNICAL FIELD

The present invention relates to a sorting device, a selecting system, a sorting method, and a program.

### BACKGROUND ART

In the operation of a digital data communication system and a storage system, measures are taken against a bit error that can occur due to various reasons. A common technique used as a measure against a bit error is error correction coding that allows correction of a bit error by adding redundant data.

The error correction coding technique is composed of an encoding process that adds redundant data to information data and generates a transmission bit sequence at the sending end and a decoding process that estimates the transmission bit sequence from a received signal sequence containing noise at the receiving end. The encoding process generally requires more computation than the decoding process, and improving the efficiency of the computation and a way of implementing the computation often arise as practical issues.

A polar code whose theoretical optimality for error correction capability is proven is well known as a common error correction technique. The polar code is employed as an error correction code for a control channel in the fifth-generation mobile communications system (5G). Non Patent Literature 1 discloses a description about the polar code. Successive Cancellation (SC) decoding disclosed in Non Patent Literature 1 and SC list decoding disclosed in Non Patent Literature 2 are well-known as methods of decoding polar codes.

The SC decoding method decodes a transmission bit sequence 1 bit by 1 bit, sequentially from the top, from a received signal sequence. However, a determination as to whether a transmission bit at a certain time is 0 or 1 is affected by a determination result on a transmission bit at an earlier time. Thus, the SC decoding method has a disadvantage that, once decoding of a transmission bit results in an error, the accuracy of a decoding result after that is not guaranteed.

Known as one solution to this problem is the SC list decoding method disclosed in Non Patent Literature 2. This method estimates transmission bits sequentially from the top in the same procedure as the SC decoding method, and it does not necessarily narrow down results to one, and continues the process of SC decoding, leaving the possibility that the result can be any one of 0 and 1. This gives a solution to the problem that once a determination results in an error, the accuracy is not guaranteed after that.

However, since the amount of computation and the memory usage are large in the SC list decoding method, it is necessary to narrow down results to several possible transmission bit sequences rather than leaving the possibility for every transmission bit sequence.

The SC list decoding method stores a list of a predetermined number of candidate transmission bit sequences and updates this list in order to prevent an exponential increase in the amount of computation. For example, when the number of candidate transmission bit sequences in the list is n, a value called a metric is assigned to each of the n number of candidate transmission bit sequences. The initial value of a metric is 0. To be specific, a metric when a transmission bit is determined to be 0 and a metric when it is determined to be 1 are computed for each point of time. The SC list decoding method selects n number of metrics with small values from total 2n number of metrics obtained in this manner, and leaves the transmission bit sequences corresponding to the selected metrics as candidates in the list. The SC list decoding method performs this process of updating the list with use of metrics repeatedly from the first bit to the last bit of a transmission bit sequence, and therefore it performs this process the same number of times as the number of transmission bits. The SC list decoding method selects one from the n number of candidate transmission bit sequences obtained finally, and uses it as a decoding result. The SC list decoding method thereby guarantees higher correction capability than the SC decoding method. Generally, as the list size n is greater, the correction capability is higher but the amount of computation increases, which is a trade-off.

The amount of computation in the SC list decoding method is almost equal to the list size (n) times the amount of computation in the SC decoding method except for the computation of metrics and the list update, which is an ascending sort of metrics, and parallel processing corresponding to the list size is possible. On the other hand, the list update is unique processing, which is not carried out in the SC decoding method, and it needs to be performed an extremely large number of times. For example, the list update is performed the same number of times as the number of transmission bits. Thus, making this processing more efficient has a large impact on enhancing the efficiency of the entire SC list decoding process. For example, reducing the number of steps required for the list update by one leads to reducing the number of steps corresponding to the number of transmission bits as a whole.

### CITATION LIST

### Patent Literature

PTL1: Japanese Unexamined Patent Application Publication No. 2007-226744
PTL2: Japanese Unexamined Patent Application Publication No. 2006-024115

### Non Patent Literature

NPL1: E. Arikan, “Channel polarization: A method for constructing capacity-achieving codes for symmetric binary-input memoryless channels,” IEEE Transactions on Information Theory, vol. 55, no. 7, pp. 3051-3073, July 2009.
NPL2; I. Tal and A. Vardy, “List decoding of polar codes,” IEEE Transactions on Information Theory, vol. 61, no. 5, pp. 2213-2226, May 2015.
NPL3: V. Bioglio, F. Gabry, L. Godard, and I. Land, “Two-step metric sorting for parallel successive cancellation list decoding of polar codes,” IEEE Commun. Lett., vol. 21, no. 3, pp. 456-459, March 2017
NPL4: H. Li, “Enhanced metric sorting for successive cancellation list decoding of polar codes,” IEEE Commun. Lett., vol. 22, no. 4, pp. 664-667, April 2018.

### SUMMARY OF INVENTION

### Technical Problem

Major processing in the list update is selecting n number of small values (metrics) from 2n number of values (metrics). This processing is generally implemented by sorting (rearranging) 2n number of values in ascending order. Various methods are known as common sorting methods, including bubble sorting disclosed in Patent Literature 1, merge sorting, and bitonic sorting. Application of those common sorting methods to the SC list decoder is disclosed in Non Patent Literature 3 and Non Patent Literature 4. However, those sorting methods sequentially repeat a 2-input comparison that compares two values. Further, Patent Literature 2 also discloses a sorting method that rearranges a plurality of data in ascending order or in descending order. However, the sorting method disclosed in Patent Literature 2 also sequentially performs sorting, assuming use of program processing. In the case where the sorting disclosed in Patent Literatures 1 and 2 is implemented by hardware, the number of stages of a logic circuit increases in proportion to the number of times of the 2-input comparison. This makes it difficult to increase the clock frequency, which causes a decrease in processing speed and an increase in the number of processing steps.

One object of the present disclosure is to provide a sorting device, a selecting system, a sorting method, and a program or a non-transitory computer readable medium storing the program capable of preventing a decrease in processing speed and an increase in the number of processing steps in list decoding including list update.

### Solution to Problem

A sorting device according to a first aspect of the present disclosure include a rank computation device configured to perform, in parallel, comparisons of numerical data Dₖ (k is an integer from 0 to n−1) included in numerical data D₀ to Dₙ₋₁ (n is an integer of 1 or more) with each of the numerical data D₀ to Dₙ₋₁ excluding the numerical data Dₖ, and compute a rank indicating a value level of the numerical data Dₖ in the numerical data D₀ to Dₙ₋₁ by using each comparison result, and a selection device configured to rearrange the numerical data D₀ to Dₙ₋₁ in order on the basis of ranks of the numerical data D₀ to Dₙ₋₁.

A selecting system according to a second aspect of the present disclosure includes a sorting device configured to perform, in parallel, comparisons of numerical data Dₖ (k is an integer from 0 to n−1) included in numerical data D₀ to Dₙ₋₁ (n is an integer of 1 or more) with each of the numerical data D₀ to Dₙ₋₁ excluding the numerical data Dₖ, compute a rank indicating a value level of the numerical data Dₖ in the numerical data D₀ to Dₙ₋₁ by using each comparison result, and rearrange the numerical data D₀ to Dₙ₋₁ in order on the basis of ranks of the numerical data D₀ to Dₙ₋₁; a selecting device configured to perform, in parallel, comparisons of numerical data Dₘ (m is an integer from n to 2n−1) included in numerical data Dₙ to D₂ₙ₋₁ with each of the numerical data Dₙ to D₂ₙ₋₁ excluding the numerical data Dₘ, compute a rank indicating a value level of the numerical data Dₘ in the numerical data Dₙ to D₂ₙ₋₁ by using each comparison result, rearrange the numerical data Dₙ to D₂ₙ₋₁ in order on the basis of ranks of the numerical data D₀ to Dₙ₋₁, and extract n/2 number of numerical data sequentially from high rank numerical data; and a comparison device configured to compare n/2 number of numerical data sequentially from low rank numerical data among the numerical data D₀ to D_{N-1} rearranged by the sorting device with the n/2 number of numerical data extracted by the selecting device, and extract n/2 number of numerical data on the basis of a comparison result. Note that n/2 indicates that n is divided by 2.

A sorting method according to a third aspect of the present disclosure includes performing, in parallel, comparisons of numerical data Dₖ (k is an integer from 0 to n−1) included in numerical data D₀ to Dₙ₋₁ (n is an integer of 1 or more) with each of the numerical data D₀ to Dₙ₋₁ excluding the numerical data Dₖ, and computing a rank indicating a value level of the numerical data Dₖ in the numerical data D₀ to Dₙ₋₁ by using each comparison result, and rearranging the numerical data D₀ to Dₙ₋₁ in order on the basis of ranks of the numerical data D₀ to Dₙ₋₁.

A program or a non-transitory computer readable medium storing a program according to a fourth aspect of the present disclosure causes a computer to execute performing, in parallel, comparisons of numerical data Dₖ (k is an integer from 0 to n−1) included in numerical data D₀ to Dₙ₋₁ (n is an integer of 1 or more) with each of the numerical data D₀ to Dₙ₋₁ excluding the numerical data Dₖ, and computing a rank indicating a value level of the numerical data Dₖ in the numerical data D₀ to Dₙ₋₁ by using each comparison result, and rearranging the numerical data D₀ to Dₙ₋₁ in order on the basis of ranks of the numerical data D₀ to Dₙ₋₁.

### Advantageous Effects of Invention

According to the present disclosure, there are provided a sorting device, a selecting system, a sorting method, and a program or a non-transitory computer readable medium storing the program capable of preventing a decrease in processing speed and an increase in the number of processing steps in list decoding including list update.

### BRIEF DESCRIPTION OF DRAWINGS

FIG. 1 is a block diagram of a low-delay sorting device according to a first example embodiment.

FIG. 2 is a block diagram of a rank computation device according to the first example embodiment.

FIG. 3 is a block diagram of a k-th rank computation device according to the first example embodiment.

FIG. 4 is a block diagram of a selection device according to the first example embodiment.

FIG. 5 is a block diagram of a k-th selection device according to the first example embodiment.

FIG. 6 is a view showing the flow of a low-delay sorting process according to a second example embodiment.

FIG. 7 is a block diagram of a (2n, n) selecting device according to the second example embodiment.

FIG. 8 is a block diagram of a (2n, n) selecting device according to the second example embodiment.

FIG. 9 is a block diagram of a list decoder of polar codes according to the first example embodiment.

FIG. 10 is a view showing a step function according to the first example embodiment.

FIG. 11 is a block diagram of a low-delay sorting device according to the first example embodiment.

### DESCRIPTION OF EMBODIMENTS

### First Example Embodiment

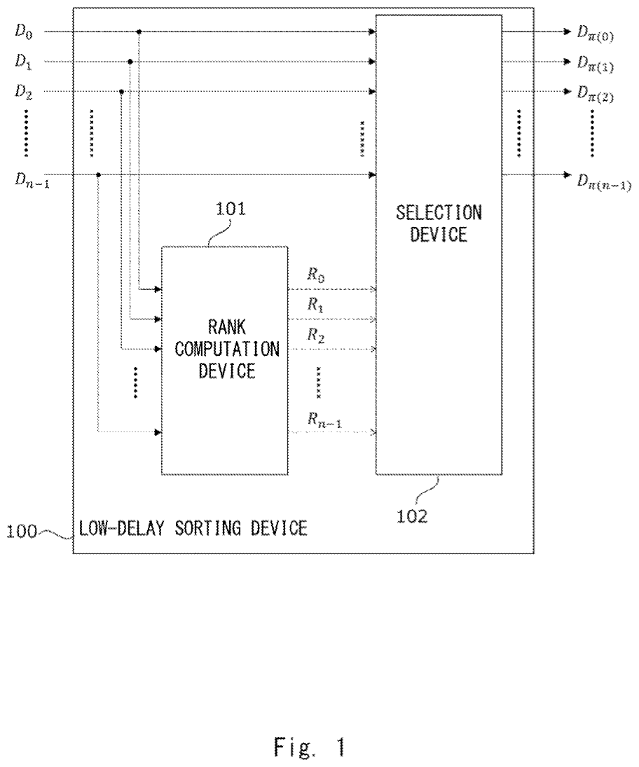

Example embodiments of the present invention will be described hereinafter with reference to the drawings. In the drawings, the arrow indicates an example of the signal or data flow, and the signal or data flow may be in two ways. A configuration example of a low-delay sorting device 100 according to the first example embodiment is described hereinafter with reference to FIG. 1.

The low-delay sorting device 100 in FIG. 1 is a device that performs sorting that rearranges numerical data in ascending order, which is required during list update in a list decoder of polar codes.

The low-delay sorting device 100 includes a rank computation device 101 and a selection device 102. Input data of the low-delay sorting device 100 according to the present disclosure is a sequence of n number of numerical values (n is an integer of 2 or more): D₀, D₁, ˜, Dₙ₋₁. The rank computation device 101 performs, in parallel, comparisons of numerical data Dₖ (k is an integer from 0 to n−1) included in the numerical data D₀, D₁, ˜, Dₙ₋₁ with each of the numerical data D₀, D₁, ˜, Dₙ₋₁ excluding the numerical data Dₖ. Further, the rank computation device 101 computes the rank indicating the value level of the numerical data Dₖ in the numerical data D₀, D₁, ˜, Dₙ₋₁ by using each comparison result.

Output data of the low-delay sorting device 100 is a sequence of numerical values D_{π(0)}, D_{π(1)}, ˜, D_{π(n-1)}, which is a result of rearranging the n number of input values in ascending order. The selection device 102 rearranges the numerical data D₀, D₁, ˜, Dₙ₋₁ in order on the basis of the ranks of the numerical data D₀, D₁, ˜, Dₙ₋₁. π represents substitution of n number of integers from 0 to n−1, and it satisfies the following inequality.

Expression 1

D_{π(0)}≤D_{π(1)}≤D_{π(2)}≤ . . . ≤D_{π(n-1)} (Equation 1)

As described above, the low-delay sorting device 100 in FIG. 1 performs, in parallel, comparisons of the numerical data Dₖ included in the numerical data D₀, D₁, ˜, Dₙ₋₁ with each of the numerical data D₀, D₁, ˜, Dₙ₋₁ excluding the numerical data Dₖ. This enables implementation of a low-delay sort circuit with a small amount of delay and a small number of processing steps, which has been difficult to be implemented by a common sorting method that sequentially performs a 2-input comparison. As a result, a list decoder of polar codes capable of high-speed processing is achieved.

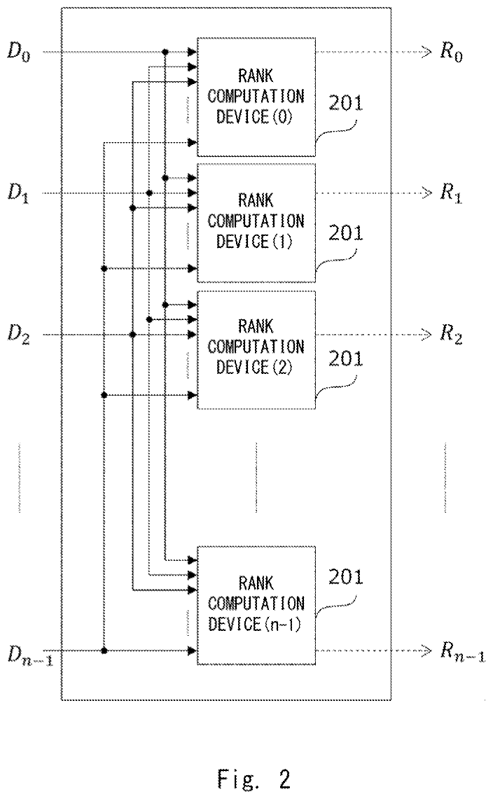

A configuration example of the rank computation device 101 according to the first example embodiment is described hereinafter with reference to FIG. 2.

FIG. 2 is a block diagram showing a configuration example of the rank computation device 101 in FIG. 1. The rank computation device 101 in FIG. 2 includes a plurality of rank computation devices 201. The rank computation devices 201 in FIG. 2 include a k-th rank computation devices (k) for each of k=0, 1, 2, ˜, n−1. The k-th rank computation devices (k) computes and outputs a rank (Rₖ) indicating in a rank order the value Dₖ in the input data is placed when counted in ascending order. The rank is represented using an integer from 0 to n−1. The first rank is 0th. The numerical data D₀, D₁, ˜, Dₙ₋₁ are respectively input to the rank computation devices (k). Each of the rank computation devices 201 in the rank computation device 101 performs parallel processing and outputs a rank.

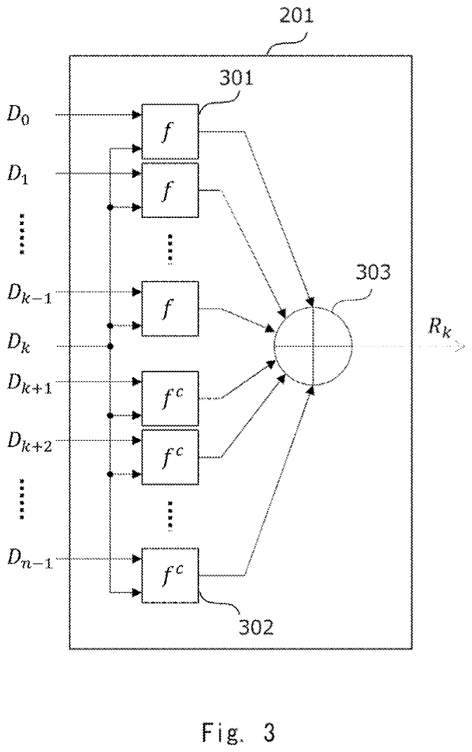

FIG. 3 is a block diagram showing a configuration example of the k-th rank computation device (k) in FIG. 2. The rank computation device (k) in FIG. 3 includes k number of step function blocks f_301, n−k−1 number of step function blocks f^{c}_302, and an adder 303. The details of the two step function blocks f_301 and f^{c}_302 are described later in Description of Operation. The k number of step function blocks f_301 and the n−k−1 number of step function blocks f^{c}_302 perform parallel processing.

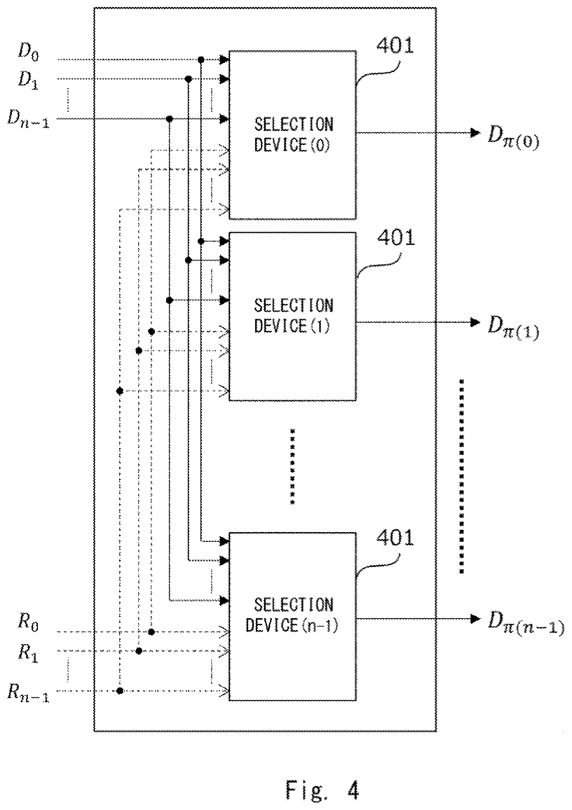

FIG. 4 is a block diagram showing a configuration example of the selection device 102 in FIG. 1. The selection device 102 in FIG. 4 includes a plurality of selection devices 401. The selection device 401 in FIG. 4 includes a k-th selection device (k) for each of k=0, 1, 2, ˜, n−1. The k-th selection device (k) selects and outputs data that is ranked in the k-th place when the n number of input data D₀, D₁, ˜, Dₙ₋₁ are rearranged in ascending order. The numerical data D₀, D₁, ˜, Dₙ₋₁ and the ranks R₀, R₁, ˜, Rₙ₋₁ are input to each of the selection devices 401.

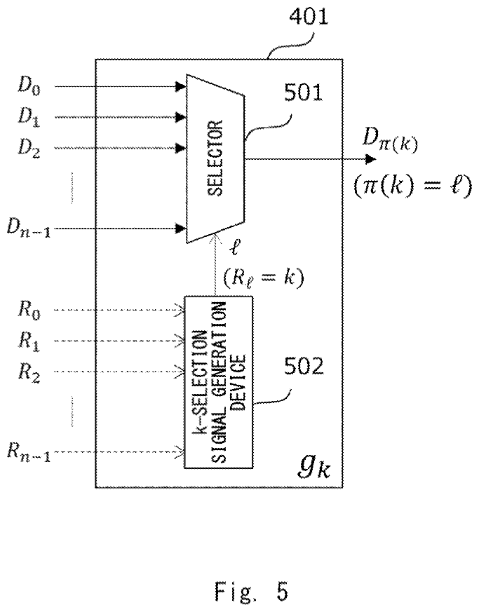

FIG. 5 is a block diagram showing a configuration example of the k-th selection device (k) in FIG. 4. The selection device (k) in FIG. 5 includes a selector 501 that selects a specified one from the n number of input data D₀, D₁, ˜, Dₙ₋₁ and a k-selection signal generation device 502 that generates a selection signal. The selection signal generated by the k-selection signal generation device 502 is used for the elector 501 to select a specified one from D₀, D₁, ˜, Dₙ₋₁. The k-selection signal generation device 502 receives R₀, R₁, ˜, Rₙ₋₁ that are output from the rank computation device 101 in FIG. 2, and outputs an index 1 that satisfies the following expression (2). 1 represents a lower-case character of the alphabetic character L.

Expression 2

[symbol]

=k (Equation 2)

As described earlier, this means that D₁ is data that is ranked in the k-th place when counted in ascending order among the input data D₀, D₁, ˜, Dₙ₋₁ in D₁ represents a lower-case character of the alphabetic character L. Thus, the selector 501 can be regarded as a device that receives the index 1 and the n number of data D₀, D₁, ˜, Dₙ₋₁ output from the k-selection signal generation device 502, and simply outputs one data D₁.

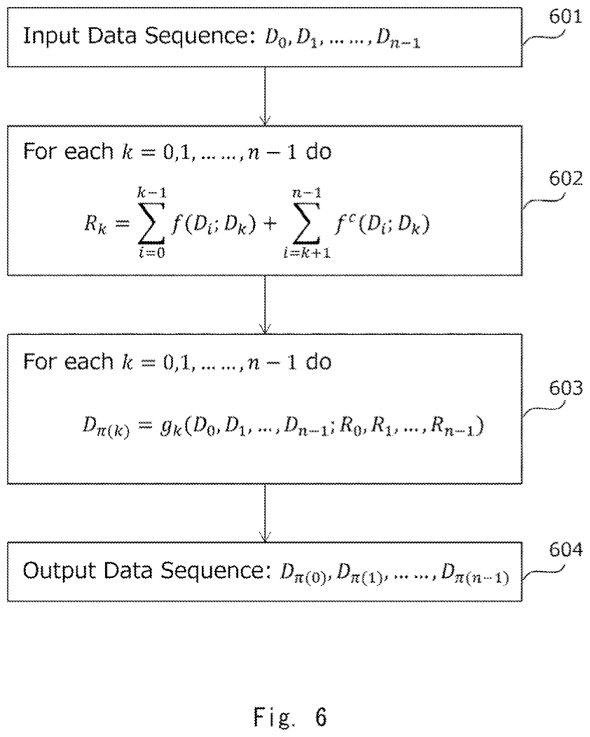

FIG. 6 shows an example of a flowchart related to a low-delay sorting method according to the present disclosure. First, the rank computation device 101 and the selection device 102 receive the n number of data D₀, D₁, ˜, Dₙ₋₁ (601). Next, the rank computation device 101 outputs Rₖ indicating the rank of Dₖ when the input data are rearranged in ascending order for each of k=0, 1, 2, ˜, n−1 (602). Then, the selection device 102 outputs data (D_{π(k)}) that is ranked in the k-th place when counted in ascending order for each of k=0, 1, 2, ˜, n−1 (603). The selection device 102 then outputs a data sequence obtained by rearranging n number of data in ascending order (604).

The low-delay sorting device 100 is able to rearrange a given numerical data sequence in descending order or in any order, not limited to ascending order.

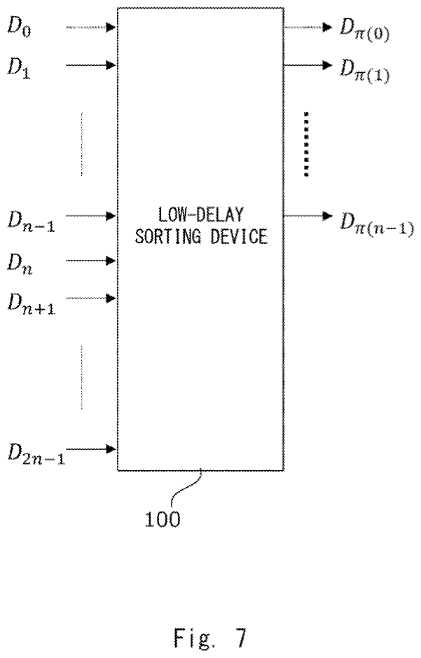

FIG. 7 is a block diagram showing a configuration example of a (2n, n) selecting device using the low-delay sorting device 100 in FIG. 1. The (2n, n) selecting device is a device that selects n number of data with small values from 2n number of input data D₀, D₁, ˜, D₂ₙ₋₁ and outputs the data.

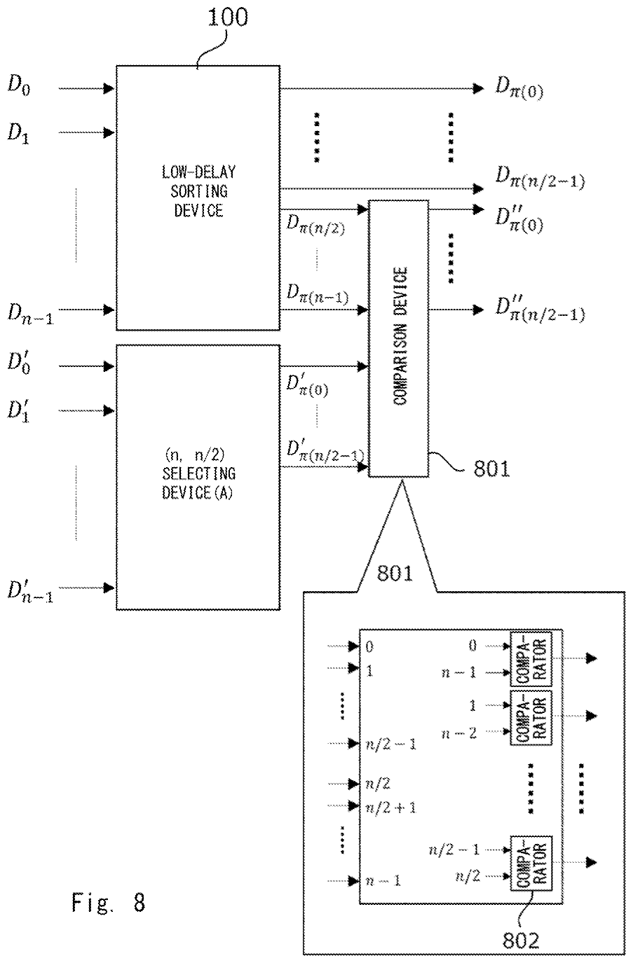

FIG. 8 shows a (2n, n) selecting device having a different configuration from that in FIG. 7, and it includes the low-delay sorting device 100 in FIG. 1 where the number of input data is n and a (n, n/2) selecting device in the configuration of FIG. 7. The (2n, n) selecting device in FIG. 8 includes a comparison device 801 in which n/2 number of common comparators 802 that output a smaller value out of two input values are arranged in parallel. Note that, in the device of FIG. 8, differently from the device of FIG. 7, 2n number of input data D₀, D₁, ˜, Dₙ₋₁, D₀′, D₁′, ˜, Dₙ₋₁′ need to satisfy the following expression 3 for all of k=0, 1, 2, ˜, n−1, thus having restrictions on input data.

Expression 3

Dₖ≤D′ₖ,k=0,1, . . . ,n−1 (Equation 3)

On the other hand, the usage of hardware resources required for implementing the (2n, n) selecting device in FIG. 8 is significantly reduced compared with that of the device in FIG. 7. Further, in the case of using the (2n, n) selecting device in FIG. 8 for a list decoder of polar codes, input data always satisfies the expression 3, and therefore the (2n, n) selecting device in FIG. 8 is useful for this purpose.

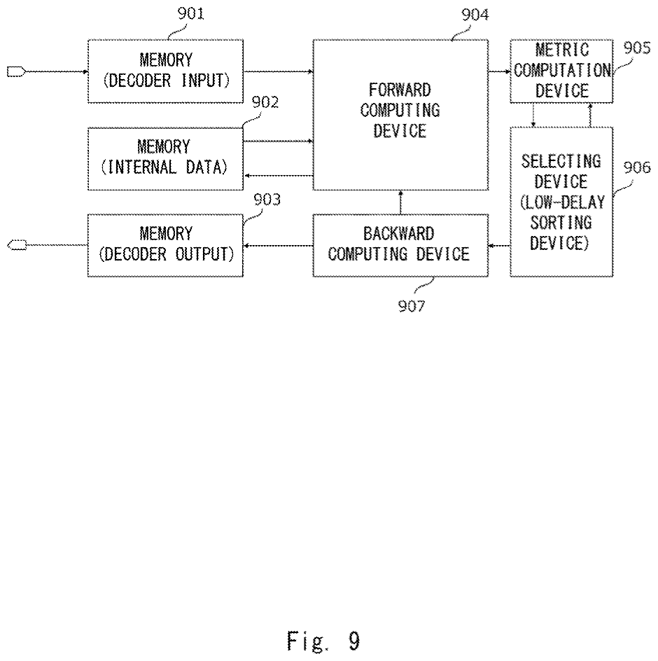

FIG. 9 is a block diagram showing a configuration example of a list decoder of polar codes that includes the selecting device shown in FIG. 7 or 8. The overview of the list decoding method is disclosed in Non Patent Literature 2, for example. The list decoder in FIG. 9 includes a memory 901 that stores decoder input, a memory 902 that stores internal data, and a memory 903 that stores a list of decoder outputs. Further, the list decoder in FIG. 9 includes a forward computing device 904 that updates the data stored in the memory 901 and the memory 902 and generates output data to be output to a metric computation device 905. The list decoder in FIG. 9 also includes a selecting device 906 in FIG. 7 or 8 that makes a selection of data from the output data of the metric computation device 905. The list decoder in FIG. 9 also includes a backward computing device 907 that generates a list of decoder outputs from the output of the selecting device 906 and generates data to be used in the forward computing device 904.

### [Description of Operation]

The operation of the low-delay sorting device 100 in FIG. 1 according to an example embodiment of the present disclosure is described hereinafter with reference to the flowchart of FIG. 6. Input to the low-delay sorting device 100 is a sequence composed of n number of numerical data (n is an integer of 2 or more), which are denoted as D₀, D₁, ˜, Dₙ₋₁ (601 in FIG. 6). Those numerical data are input to the rank computation device 101 and the selection device 102.

The rank computation device 101 calculates ranks R₀, R₁, ˜, Rₙ₋₁ when the n number of numerical data D₀, D₁, ˜, Dₙ₋₁ are rearranged in ascending order by using the following expression 4 (602 in FIG. 6).

$$\begin{matrix}Expression 4 & \\ {R}_{k} = {\sum }_{i = 0}^{k - 1} f ( {D}_{i} ; {D}_{k} ) + {\sum }_{i = k + 1}^{n - 1} {f}^{C} ( {D}_{i} ; {D}_{k} ) , \\ k = 0 , 1 , … , n - 1 & ( Equation 4 )\end{matrix}$$

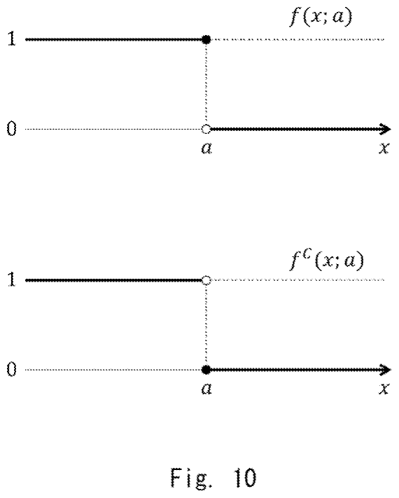

In the expression 4, each of f and f^{c} represents the step function shown in FIG. 10. Specifically, the first term in the expression 4 represents the number of numerical data whose value is Dₖ or less (including numerical data whose value is Dₖ) among D₀, D₁, ˜, Dₖ₋₁. The second term in the expression 4 represents the number of numerical data whose value is less than Dₖ (not including numerical data whose value is Dₖ) among Dₖ₊₁, Dₖ₊₂, ˜, Dₙ₋₁. In this manner, Rₖ in the expression 4 represents the rank of Dₖ in D₀, D₁, ˜, Dₙ₋₁. Note that the two types of step functions f and f^{c} are used so as to compute the rank without fail even when the same value exists in D₀, D₁, ˜, Dₙ₋₁.

In the configuration example of the rank computation device 101 shown in FIG. 2, the 0th rank computation device (0) is a device that performs processing when k=0 in the expression 4. Likewise, the k-th rank computation device (k) exists for each of k=0, 1, 2, ˜, n−1. FIG. 3 shows an example where the k-th rank computation device (k) includes the blocks f_301 and f^{c}_302 having two types of step functions and the adder 303.

The selection device 102 is a device that receives input numerical data D₀, D₁, ˜, Dₙ₋₁ and rank data R₀, R₁, ˜, Rₙ₋₁ computed by the rank computation device 101, and rearranges the input numerical data in ascending order. The selection device 102 shown in FIG. 4 includes n number of selection devices 401 from the 0-th selection device (0) to the (n−1)th selection device (n−1). For k=0, 1, 2, ˜, n−1, the k-th selection device (k) includes the k-selection signal generation device 502 and the selector 501 as shown in FIG. 5. The k-th selection device (k) selects D₁ by the selector with use of the index 1 that satisfies the expression 2 which is calculated by the k-selection signal generation device 502. D₁ is the k-th numerical data when counted in ascending order, and it is denoted as D_{π(k)}.

Processing 603 in the flowchart of FIG. 6 shows the operation of the k-th selection device (k) in FIG. 5 by using symbols. Note that, by changing the placement of the k-th selection device (k) in the selection device in FIG. 4, there can be provided a device that rearranges data in descending order or in any order, not limited to ascending order.

The operation of the (2n, n) selecting device shown in FIG. 7 is described hereinbelow. The (2n, n) selecting device inputs 2n number of input data D₀, D₁, ˜, D₂ₙ₋₁ to the low-delay sorting device in FIG. 1 (the number of input is 2n), and outputs highly ranked n number of data D_{π(0)}, D_{π(1)}, ˜, D_{π(n-1)} among its output data D_{π(0)}, D_{π(1)}, ˜, D_{π(2n-1)}. The operation of the (2n, n) selecting device is the same as shown in FIG. 1.

The operation of the (2n, n) selecting device shown in FIG. 8 is described hereinafter. The (2n, n) selecting device in FIG. 8 receives, as input, 2n number of data D₀, D₁, ˜, D₂ₙ₋₁ and D₀′, D₁′, ˜, D₂ₙ₋₁′ that satisfy the inequality of the expression 3, rearranges them in ascending order, and outputs the top n number of data. The (2n, n) selecting device in FIG. 8 includes the low-delay sorting device 100 in FIG. 1 and the (n, n/2) selecting device where the number of input data is n and having the configuration shown in FIG. 7. The low-delay sorting device 100 in FIG. 1 receives data D₀, D₁, ˜, Dₙ₋₁ as input, and the (n, n/2) selecting device receives data D₀, D₁′, ˜, Dₙ₋₁′ as input. The low-delay sorting device 100 in FIG. 1 generates corresponding output data D_{π(0)}, D_{π(1)}, ˜, D_{π(n-1)}, and the (n, n/2) selecting device generates D_{π(0)}′, D_{π(1)}′, ˜, D_{π(n/2-1)}′. Among the outputs of the low-delay sorting device 100 in FIG. 1, low-rank n/2 number of data D_{π(n/2)}, D_{π(n/2+1)}, ˜, D_{π(n-1)} and n/2 number of output data D_{π(0)}′, D_{π(1)}′, ˜, D_{π(n/2-1)}′ of the (n, n/2) selecting device are input to the comparison device 801. The comparison device 801 includes n/2 number of comparators 802, and each of them yields D_{π(k)}″ where k=0, 1, 2, ˜, n/2−1 that is represented by the following expression 5.

Expression 5

D″_{π(k)}=min{D_{n/2+k},D′_{π(n/2-1-k)}} (Equation 5)

When the input data satisfies the inequality of the expression 3, the high rank n/2 number of data D_{π(0)}, D_{π(1)}, ˜, D_{π(n/2-1)} among the outputs of the low-delay sorting device 100 and n/2 number of data D_{π(0)}″, D_{π(1)}″, ˜, D_{π(n/2-1)}″ selected in the expression 5 are desired outputs. Note that, although the outputs of the (2n, n) selecting device in FIG. 8, differently from that in FIG. 7, are not necessarily arranged in ascending order, it has the function of selecting and outputting the top n number of data among 2n number of input data.

The operation of the list decoder of polar codes shown in FIG. 9 that includes the selecting device shown in FIG. 7 or 8 is described hereinafter. A common list decoding method is disclosed in Non Patent Literature 2, for example, and therefore the detailed description thereof is omitted, and the description related to the present disclosure is mainly provided below.

Input of the list decoder in FIG. 9 is a log-likelihood ratio (LLR), which is the output of a communication channel, and when the frame length is N bits, real values L₀, L₁, ˜, L_{N-1}, which represent N number of LLRs, are stored in the decoder input memory 901. The list decoder generates a list of candidate transmission data sequences 1 bit by 1 bit from time 0 to N−1.

The forward computing device 904 has two data processing functions P₁(x,y), P₂(x,y,z) for input data x, y, z (x and y are LLR data, z is 0 or 1), which are represented by the following expression 6.

$$\begin{matrix}Expression 6 & \\ {P}_{1} ( x , y ) = 2 {tanh}^{- 1} ( tanh ( \frac{x}{2} ) tanh ( \frac{y}{2} ) ) \\ {P}_{2} ( x , y , z ) = {( - 1 )}^{z} x + y & ( Equation 6 )\end{matrix}$$

The forward computing device 904 generates internal LLR data Lⱼ⁽ⁱ⁾[1] by the following expressions 7 and 8 from the LLR data stored in the decoder input memory 901 or the internal data memory 902, and stores it into the memory 902. l represents a lower-case character of the alphabetic character L.

Expression 7

Lₖ^{(p)}[ [symbol] ]←P₂(L₂ₖ^{(p-1)}[ [symbol] ],L₂ₖ₊₁^{(p-1)}[ [symbol] ],vₖ[ [symbol] ]) (Equation 7)

Expression 8

Lⱼ⁽ⁱ⁾[ [symbol] ]←P₁(L₂ⱼ⁽ⁱ⁻¹⁾[ [symbol] ],L₂ⱼ₊₁⁽ⁱ⁻¹⁾[ [symbol] ]) (Equation 8)

In the expression 7, p represents a certain integer between 1 and m(=log₂N) that is specified by time t, and k represents an integer between 0 and N/2^{p}−1. Further, in the expression 8, i represents an integer between p+1 and m, and j represents an integer between 0 and N/2ⁱ−1. In the expressions 7 and 8, 1 is an integer value representing a list number, and 1 represents an integer value between 0 and n−1 when a previously specified list size is n. Note that the initial values L₀⁽⁰⁾[0], L₀⁽⁰⁾[0], ˜, Lₙ₋₁⁽⁰⁾[0] of the internal LLR data are decoder inputs L₀, L₁, ˜, L_{N-1} that are stored in the decoder input memory 901, and L₀⁽⁰⁾[1], L₁⁽⁰⁾[1], ˜, L_{N-1}⁽⁰⁾[1] are previously specified values for 1≠0. A previously specified value may be a sufficiently large value, for example. Although the processing of the expressions 7 and 8 can be processed in parallel for 1 representing the list number and also for the index k or j, parallel processing cannot be performed for the index i since it is sequential processing.

At an arbitrary time t, after the operation of the expression 7 is done (at time t=0, the operation of the expression 7 is skipped with p=0), the expression 8 is repeatedly applied in the sequence of i=p+1, p+2, ˜ to obtain n number of internal LLR data L₀^{(m)}[0], L₀^{(m)}[1], ˜, L₀^{(m)}[n−1]. Then, the n number of internal LLR data are input to the metric computation device 905.

The metric computation device 905 performs processing of the following expression 9 from the n number of data D₀, D₁, ˜, Dₙ₋₁ (the initial value is 0) stored in the device and the n number of internal LLR data. The metric computation device 905 outputs total 2n number of metrics and values D₀, D₁, ˜Dₙ₋₁, ˜, D₂ₙ₋₁ associated with the respective metrics to the selecting device 906.

Expression 9

[symbol]

← [symbol] +|L₀^{(m)}[ [symbol] ]|, [symbol] =0,1, . . . ,n−1 (Equation 9)

The (2n, n) selecting device in FIG. 7 or 8 that uses the low-delay sorting device 100 according to the present disclosure selects n number of metrics (D_{π(0)}, D_{π(1)}, ˜, D_{π(n-1)}) with small values from the 2n number of metrics. Further, the (2n, n) selecting device in FIG. 7 or 8 returns the n number of metrics to the metric computation device 905 for use in the operation at the next time, and also outputs it to the backward computing device 907. Note that it is obvious from the expression 9 that when Dₖ′=Dₖ₊ₙ, the 2n number of input data input to the selecting device satisfy the expression 3, and therefore they meet the conditions of application of the selecting device in FIG. 8.

The backward computing device 907 determines 0 or 1 on the basis of whether the outputs D_{π(0)}, D_{π(1)}, ˜, D_{π(n-1)} of the selecting device are positive of negative, and outputs them as a list of decoder output data at time t to the memory 903. Further, the backward computing device 907 generates binary data vₖ[1] to use in the expression 7 in the forward computing device 904. Furthermore, the backward computing device 907 changes address generation when the forward computing device 904 accesses the internal data memory 902 according to information π(0), π(1), ˜π(n−1) obtained from the selecting device 906. After that, time t is incremented to time t+1, and the above processing is repeated.

As described above, sorting and selection of metric data according to the present disclosure are sequentially incorporated into a series of processing operations occurring at each time in a series of operations of list decoding of polar codes. Therefore, reduction of the number of processing steps required for the sorting and selection of metric data significantly contributes to reduction of the number of processing steps required for the entire list decoding.

### Specific Example

A specific example related to the low-delay sorting in FIG. 1 or 6 according to the present disclosure is described hereinafter. In the following description, an example where the number n of input data is 16 is described. The 16 numerical values shown in the row Dₖ (the second row) in Table 1 below are input data of the low-delay sorting device 100 in FIG. 1.

TABLE 1

| k | 0 | 1 | 2 | 3 | 4 | 5 | 6 | 7 | 8 | 9 | 10 | 11 | 12 | 13 | 14 | 15 |
|---|---|---|---|---|---|---|---|---|---|---|---|---|---|---|---|---|
| Dₖ | 11 | 42 | 12 | 21 | 44 | 1 | 11 | 83 | 53 | 81 | 21 | 86 | 53 | 54 | 90 | 88 |
| Rₖ | 1 | 6 | 3 | 4 | 7 | 0 | 2 | 12 | 8 | 11 | 5 | 13 | 9 | 10 | 15 | 14 |
| D_{π(k)} | 1 | 11 | 11 | 12 | 21 | 21 | 42 | 44 | 53 | 53 | 54 | 81 | 83 | 86 | 88 | 90 |

The 16 input data are input to the rank computation device 101, and the ranks when they are rearranged in ascending order are computed using the expression 4. The values 0 to 15 shown in the row Rₖ (the third row) in Table 1 are rank data obtained in this manner. The 16 input data and the rank data are input to the selection device 102 and rearranged, and thereby the row D_{π(k)} (the last row) in Table 1 are obtained. It is easily recognizable from Table 1 that the data are rearranged in ascending order.

The same applies to the specific example of the selecting device in FIG. 7, and the last row with k=0˜7 in Table 1 are outputs of a (16,8) selecting device (8 values from the smallest among 16 input data).

An example related to the selecting device in FIG. 8 is described hereinafter. The number of input data is assumed to be 16 as in the above description. The first 8 data among the 16 input data in Table 1 are input as D₀, D₁, ˜, D₇ to the low-delay sorting device 100, and the last 8 data are input as D₀′, D₁′, ˜, D₇′ to the (8,4) selecting device in the configuration of FIG. 7. It is obvious that the input data, 8 data each, satisfies the inequality of the expression 3.

TABLE 2

| k | 0 | 1 | 2 | 3 | 4 | 5 | 6 | 7 |
|---|---|---|---|---|---|---|---|---|
| Dₖ | 11 | 42 | 12 | 21 | 44 | 1 | 11 | 83 |
| Rₖ | 1 | 5 | 3 | 4 | 6 | 0 | 2 | 7 |
| D_{π(k)} | 1 | 11 | 11 | 12 | 21 | 42 | 44 | 83 |
| D′ₖ | 53 | 81 | 21 | 86 | 53 | 54 | 90 | 88 |
| R′ₖ | 1 | 4 | 0 | 5 | 2 | 3 | 7 | 6 |
| D′_{π(k)} | 21 | 53 | 53 | 54 | 81 | 86 | 88 | 90 |

Table 2 shows an example of applying the low-delay sorting process where the number of input is 8, and the (8,4) selecting process. As in the case of Table 1, after computing each of the rank data Rₖ and Rₖ′ (the third row in each table of Table 2), the data are sorted using the rank data, so that D_{π(k)} and D_{π(k)}′ are obtained (the last row in each table of Table 2).

It is found from the expression 5 that D_{π(0)}″, D_{π(1)}″, D_{π(2)}″, D_{π(3)}″ are 21, 42, 44, 21, respectively. Thus, the outputs of the (16,8) selecting device in FIG. 8 are 1, 11, 11, 12, 21, 42, 44, 21, and the output data corresponds (as a set; the rank order is different) to the outputs of the (16,8) selecting device in FIG. 7.

In the case where the number of data input is 16 or 32, when the low-delay sorting device 100 according to the present disclosure is implemented using a standard FPGA (Field Programmable Gate Array), the number of logical stages and the processing delay required for a hardware circuit for sorting are reduced to about ⅙ to ⅓ when compared with bubble sorting (see Patent Literature 1, for example). The same effect is obtained also when compared with merge sorting instead of bubble sorting.

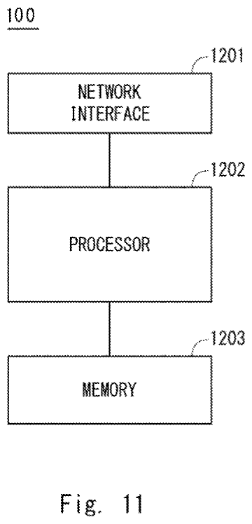

FIG. 11 is a block diagram showing a configuration example of the low-delay sorting device 100. Referring to FIG. 11, the low-delay sorting device 100 includes a network interface 1201, a processor 1202, and a memory 1203. The network interface 1201 is used to communicate with another network node that constitutes the communication system. The network interface 1201 may include a network interface card (NIC) that complies with the IEEE 802.3 series, for example. Alternatively, the network interface 1201 may be used to perform radio communication. For example, the network interface 1201 may be used to perform wireless LAN communication or mobile communication defined by 3GPP (3rd Generation Partnership Project).

The processor 1202 reads and runs software (computer program) from the memory 1203 and thereby executes processing of the low-delay sorting (processing) device 100 that is described with reference to the flowchart or the sequence chart in the example embodiments described above. The processor 1202 may be a microprocessor, an MPU (Micro Processing Unit) or a CPU (Central Processing Unit), for example. The processor 1202 may include a plurality of processors.

The memory 1203 is a combination of a volatile memory and a nonvolatile memory. The memory 1203 may include a storage that is placed apart from the processor 1202. In this case, the processor 1202 may access the memory 1203 through an I/O interface, which is not shown.

In the example of FIG. 11, the memory 1203 is used to store a group of software modules. The processor 1202 performs the processing of the low-delay sorting (processing) device 100 described in the above example embodiments by reading the group of software modules from the memory 1203 and executing them.

As described with reference to FIG. 11, each of processors included in the low-delay sorting device 100 runs one or a plurality of programs including a group of instructions for causing a computer to perform the algorithms described using the drawings.

In the above-described examples, the program can be stored and provided to a computer using any type of non-transitory computer readable medium. The non-transitory computer readable medium includes any type of tangible storage medium. Examples of the non-transitory computer readable medium include magnetic storage media (such as floppy disks, magnetic tapes, hard disk drives, etc.), optical magnetic storage media (e.g. magneto-optical disks), CD-ROM (Read Only Memory), CD-R, CD-R/W, and semiconductor memories (such as mask ROM, PROM (Programmable ROM), EPROM (Erasable PROM), flash ROM, RAM (Random Access Memory), etc.). The program may be provided to a computer using any type of transitory computer readable medium. Examples of the transitory computer readable medium include electric signals, optical signals, and electromagnetic waves. The transitory computer readable medium can provide the program to a computer via a wired communication line such as an electric wire or optical fiber or a wireless communication line.

Note that the present disclosure is not limited to the above-described example embodiments and can be modified as appropriate without departing from the spirit and scope of the present disclosure.

The whole or part of the example embodiments disclosed above can be described as, but not limited to, the following supplementary notes.

### (Supplementary Note 1)

A sorting device comprising:

a rank computation device configured to perform, in parallel, comparisons of numerical data Dₖ (k is an integer from 0 to n−1) included in numerical data D₀ to Dₙ₋₁ (n is an integer of 1 or more) with each of the numerical data D₀ to Dₙ₋₁ excluding the numerical data Dₖ, and compute a rank indicating a value level of the numerical data Dₖ in the numerical data D₀ to Dₙ₋₁ by using each comparison result; and

a selection device configured to rearrange the numerical data D₀ to Dₙ₋₁ in order on the basis of ranks of the numerical data D₀ to Dₙ₋₁.

### (Supplementary Note 2)

The sorting device according to Supplementary Note 1, wherein the rank computation device performs, in parallel, a comparison related to the numerical data Dₖ and a comparison related to the numerical data Dₖ₊₁.

### (Supplementary Note 3)

The sorting device according to Supplementary Note 2, wherein the rank computation device performs, in parallel, comparisons related to each of the numerical data D₀ to Dₙ₋₁.

### (Supplementary Note 4)

The sorting device according to any one of Supplementary Notes 1 to 3, wherein the rank computation device includes 0th to (n−1)th rank computation units, and a comparison related to the numerical data Dₖ is performed in a k-th rank computation unit.

### (Supplementary Note 5)

The sorting device according to Supplementary Note 4, wherein the k-th rank computation unit includes:

a first comparison unit configured to compare the numerical data Dₖ with each of numerical data D₀ to Dₖ₋₁, and outputs 1 when a value of the numerical data Dₖ is equal to or smaller than values of other numerical data, and outputs 0 when a value of the numerical data Dₖ is greater than values of other numerical data;

a second comparison unit configured to compare the numerical data Dₖ with each of numerical data Dₖ+1 to Dₙ₋₁, and outputs 1 when a value of the numerical data Dₖ is smaller than values of other numerical data, and outputs 0 when a value of the numerical data Dₖ is equal to or greater than values of other numerical data; and

an adder configured to add values output from the first comparison unit and the second comparison unit.

### (Supplementary Note 6)

The sorting device according to any one of Supplementary Notes 1 to 5, wherein the selection device includes 0th to (n−1)th selection units, and numerical data with a k-th value is output from a k-th selection unit.

### (Supplementary Note 7)

The sorting device according to Supplementary Note 6, wherein the k-th selection unit includes a selector configured to receive, as input, the numerical data D₀ to Dₙ₋₁ and an instruction signal indicating output of numerical data in k-th rank, and output numerical data associated with the k-th rank.

### (Supplementary Note 8)

The sorting device according to any one of Supplementary Notes 1 to 7, wherein the selection device selects a predetermined number of numerical data sequentially from high rank numerical data.

### (Supplementary Note 9)

A selecting system comprising:

a sorting device configured to perform, in parallel, comparisons of numerical data Dₖ (k is an integer from 0 to n−1) included in numerical data D₀ to Dₙ₋₁ (n is an integer of 1 or more) with each of the numerical data D₀ to Dₙ₋₁ excluding the numerical data Dₖ, compute a rank indicating a value level of the numerical data Dₖ in the numerical data D₀ to Dₙ₋₁ by using each comparison result, and rearrange the numerical data D₀ to Dₙ₋₁ in order on the basis of ranks of the numerical data D₀ to Dₙ₋₁;

a selecting device configured to perform, in parallel, comparisons of numerical data Dₘ (m is an integer from n to 2n−1) included in numerical data Dₙ to D₂ₙ₋₁ with each of the numerical data Dₙ to D₂ₙ₋₁ excluding the numerical data Dₘ, compute a rank indicating a value level of the numerical data Dₘ in the numerical data Dₙ to D₂ₙ₋₁ by using each comparison result, rearrange the numerical data Dₙ to D₂ₙ₋₁ in order on the basis of ranks of the numerical data D₀ to Dₙ₋₁, and extract n/2 number of numerical data sequentially from high rank numerical data; and

a comparison device configured to compare n/2 number of numerical data sequentially from low rank numerical data among the numerical data D₀ to D_{N-1} rearranged by the sorting device with the n/2 number of numerical data extracted by the selecting device, and extract n/2 number of numerical data on the basis of a comparison result.

### (Supplementary Note 10)

The selecting system according to Supplementary Note 9, wherein

the sorting device performs, in parallel, a comparison related to the numerical data Dₖ and a comparison related to the numerical data Dₖ₊₁, and

the selecting device performs, in parallel, a comparison related to the numerical data Dₘ and a comparison related to the numerical data Dₘ₊₁.

### (Supplementary Note 11)

A sorting method comprising:

performing, in parallel, comparisons of numerical data Dₖ (k is an integer from 0 to n−1) included in numerical data D₀ to Dₙ₋₁ (n is an integer of 1 or more) with each of the numerical data D₀ to Dₙ₋₁ excluding the numerical data Dₖ, and computing a rank indicating a value level of the numerical data Dₖ in the numerical data D₀ to Dₙ₋₁ by using each comparison result; and

rearranging the numerical data D₀ to Dₙ₋₁ in order on the basis of ranks of the numerical data D₀ to Dₙ₋₁.

### (Supplementary Note 12)

A program causing a computer to execute:

performing, in parallel, comparisons of numerical data Dₖ (k is an integer from 0 to n−1) included in numerical data D₀ to Dₙ₋₁ (n is an integer of 1 or more) with each of the numerical data D₀ to Dₙ₋₁ excluding the numerical data Dₖ, and computing a rank indicating a value level of the numerical data Dₖ in the numerical data D₀ to Dₙ₋₁ by using each comparison result; and rearranging the numerical data D₀ to Dₙ₋₁ in order on the basis of ranks of the numerical data D₀ to Dₙ₋₁.

### REFERENCE SIGNS LIST

100 LOW-DELAY SORTING DEVICE
101 RANK COMPUTATION DEVICE
102 SELECTION DEVICE
201 RANK COMPUTATION DEVICE
301 STEP FUNCTION BLOCK
302 STEP FUNCTION BLOCK
303 ADDER
401 SELECTION DEVICE
501 SELECTOR
502 K-SELECTION SIGNAL GENERATION DEVICE
801 COMPARISON DEVICE
802 COMPARATOR
901 MEMORY
902 MEMORY
903 MEMORY
904 FORWARD COMPUTING DEVICE
905 METRIC COMPUTATION DEVICE
906 SELECTING DEVICE
907 BACKWARD COMPUTING DEVICE

What is claimed is:

1. A sorting device comprising:
a rank computation device; and
a selection device;
wherein the rank computation device comprises;
at least one memory storing instructions, and
at least one processor configured to execute the instructions to;
perform, in parallel, comparisons of numerical data Dₖ (k is an integer from 0 to n−1) included in numerical data D₀ to Dₙ₋₁ (n is an integer of 1 or more) with each of the numerical data D₀ to Dₙ₋₁ excluding the numerical data Dₖ, and compute a rank indicating a value level of the numerical data Dₖ in the numerical data D₀ to Dₙ₋₁ by using each comparison result; and
wherein the selection device comprises;
at least one memory storing instructions, and
at least one processor configured to execute the instructions to;
rearrange the numerical data D₀ to Dₙ₋₁ in order on the basis of ranks of the numerical data D₀ to Dₙ₋₁.

2. The sorting device according to claim 1, wherein the at least one processor of the rank computation device is further configured to execute the instructions to perform, in parallel, a comparison related to the numerical data Dₖ and a comparison related to the numerical data Dₖ₊₁.

3. The sorting device according to claim 2, wherein the at least one processor of the rank computation device is further configured to execute the instructions to perform, in parallel, comparisons related to each of the numerical data D₀ to Dₙ₋₁.

4. The sorting device according to claim 1, wherein the rank computation device is configured to include 0th to (n−1)th rank computation units, and a comparison related to the numerical data Dₖ is performed in a k-th rank computation unit.

5. The sorting device according to claim 4, wherein the k-th rank computation unit is configured to include:
a first comparison unit configured to compare the numerical data Dₖ with each of numerical data D₀ to Dₖ₋₁, and outputs 1 when a value of the numerical data Dₖ is equal to or smaller than values of other numerical data, and outputs 0 when a value of the numerical data Dₖ is greater than values of other numerical data;
a second comparison unit configured to compare the numerical data Dₖ with each of numerical data Dₖ+1 to Dₙ₋₁, and outputs 1 when a value of the numerical data Dₖ is smaller than values of other numerical data, and outputs 0 when a value of the numerical data Dₖ is equal to or greater than values of other numerical data; and
an adder configured to add values output from the first comparison unit and the second comparison unit.

6. The sorting device according to claim 1, wherein the selection device is configured to include 0th to (n−1)th selection units, and numerical data with a k-th value is output from a k-th selection unit.

7. The sorting device according to claim 6, wherein the k-th selection unit is configured to include a selector configured to receive, as input, the numerical data D₀ to Dₙ₋₁ and an instruction signal indicating output of numerical data in k-th rank, and output numerical data associated with the k-th rank.

8. The sorting device according to claim 1, wherein the at least one processor of the selection device is further configured to execute the instructions to select a predetermined number of numerical data sequentially from high rank numerical data.

9-10. (canceled)

11. A sorting method comprising:
performing, in parallel, comparisons of numerical data Dₖ (k is an integer from 0 to n−1) included in numerical data D₀ to Dₙ₋₁ (n is an integer of 1 or more) with each of the numerical data D₀ to Dₙ₋₁ excluding the numerical data Dₖ, and computing a rank indicating a value level of the numerical data Dₖ in the numerical data D₀ to Dₙ₋₁ by using each comparison result; and
rearranging the numerical data D₀ to Dₙ₋₁ in order on the basis of ranks of the numerical data D₀ to Dₙ₋₁.

12. A non-transitory computer readable medium storing a program causing a computer to execute:
performing, in parallel, comparisons of numerical data Dₖ (k is an integer from 0 to n−1) included in numerical data D₀ to Dₙ₋₁ (n is an integer of 1 or more) with each of the numerical data D₀ to Dₙ₋₁ excluding the numerical data Dₖ, and computing a rank indicating a value level of the numerical data Dₖ in the numerical data D₀ to Dₙ₋₁ by using each comparison result; and
rearranging the numerical data D₀ to Dₙ₋₁ in order on the basis of ranks of the numerical data D₀ to Dₙ₋₁.
